(19) United States
(12) Patent Application Publication
(10) Pub. No.: US 2012/0162929 A1
(43) Pub. Date: Jun. 28, 2012

(54) POWER SUPPLY WITH SOLID INSULATING SUBSTANCE

(75) Inventor: Chao-Jui HUANG, Taipei Hsien (TW)

(73) Assignee: Chicony Power Technology Co., Ltd.

(21) Appl. No.: 12/975,462

(22) Filed: Dec. 22, 2010

(51) Int. Cl. H05K 7/00

(52) U.S. Cl. 361/728

(57) ABSTRACT

A power supply includes a casing, an electronic module and a filler having a solid insulating substance, and the casing has a cavity for installing the electronic module, and a filling space reserved from an internal wall of the casing, and the filler having the solid insulating substance is filled into the filling space, such that the consumption of potting can be reduced to lower the cost of the potting and meet the application requirements of the power supply.

### FIELD OF THE INVENTION

The present invention relates to a power supply, in particular to a power supply that requires a potting.

### BACKGROUND OF THE INVENTION

In general, a conventional voltage converter includes a sealed casing for installing electronic elements such as a voltage induction coil, an electronic component and a circuit board. The issues of heat dissipation and safety specification must be taken into consideration for the installation of these internal electronic elements, so that after the electronic elements are installed and fixed, a filling space is generally reserved in the casing for filling (or potting) a specific encapsulant therein to achieve the effects of resisting water, EMI, and noise and provide the waterproof, insulating and impedance resisting functions.

In the aforementioned structure, the specific encapsulant have one or more functions, and thus are very expensive. Particularly, when the filling space is large, it is necessary to fill up the whole filling space by the specific encapsulant. As a result, the cost of the voltage converter will increase substantially. In addition, it is not necessary to pot the whole filling space before the desired functions can be achieved. The aforementioned potting method will cause an unnecessary waste of the specific encapsulant and incur a relatively high cost.

In view of the aforementioned shortcomings of the prior art, the inventor of the present invention based on years of experience in the related industry to conduct extensive researches and experiments, and finally developed a power supply in accordance with the present invention to overcome the shortcomings of the prior art.

### SUMMARY OF THE INVENTION

Therefore, the present invention is to provide a power supply with a solid insulating substance, and the consumption of potting can be reduced to lower the cost of potting and meet the requirements of a practical application without affecting the functions of the power supply.

Accordingly, the present invention discloses a power supply with a solid insulating substance, and the power supply comprises a casing, an electronic module and a filler having a solid insulating substance, wherein the casing includes a cavity for installing an electronic module, and a filling space reserved within an internal wall of the casing for filling a filler having a solid insulating substance.

Another, the present invention is to provide a power supply with a solid insulating substance, and the solid insulating substance is a material in compliance with the UL 94 standard, or any other refractory or fire resistant material to achieve the effects of resisting fire, water, EMI, heat conduction and impedance.

Further, the present invention is to provide a power supply with a solid insulating substance, and a filler is filled into a filling space partially according to the actual requirements to reduce the consumption of an encapsulant, so as to lower the cost of potting.

Compared with the prior art, the solid insulating substance of the power supply of the present invention is composed of polycarbonate (PC) and nylon with a lower cost and filled into the filling space after it is mixed with an encapsulant, so that the consumption of the encapsulant can be reduced to lower the cost of potting. In addition, the solid insulating substance can meet the requirements to provide the functions of resisting water, dust and thermal conduction. The solid insulating substance is a material in compliance with the UL 94 standard or any other refractory or fire resistant material, so that the present invention has the function of resisting fire, water, EMI, thermal conduction and impedance. In addition, the filler is filled into the filling space partially as required, and thus the present invention is convenient and practical.

### BRIEF DESCRIPTION OF THE DRAWINGS

FIG. 1 is a partial perspective cross-sectional view of a power supply with a solid insulating substance in accordance with the present invention;

FIG. 2 is a perspective exploded view of a power supply with a solid insulating substance in accordance with the present invention; and

FIG. 3 is a cross-sectional view of an assembled power supply with a solid insulating substance in accordance with the present invention.

### DESCRIPTION OF THE PREFERRED EMBODIMENTS

The technical characteristics and contents of the present invention will become apparent with the following detailed description accompanied with related drawings. The drawings are provided for the purpose of illustrating the present invention only, but not intended for limiting the scope of the invention.

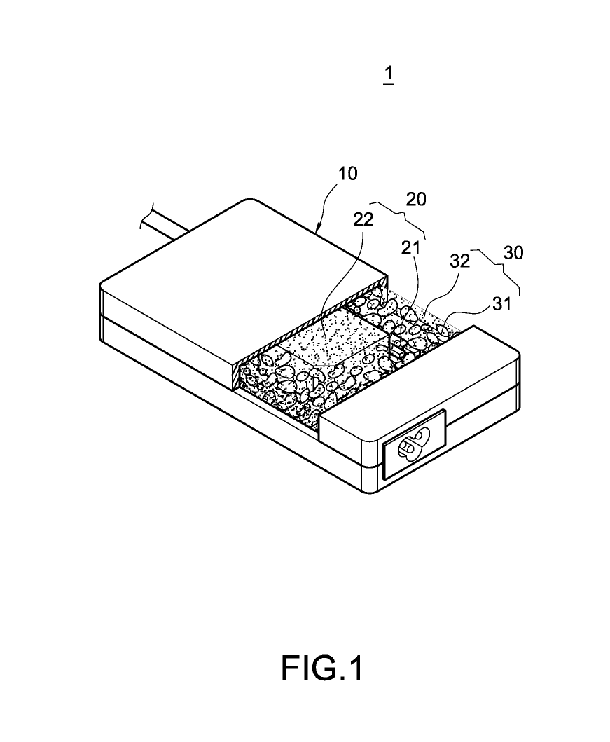

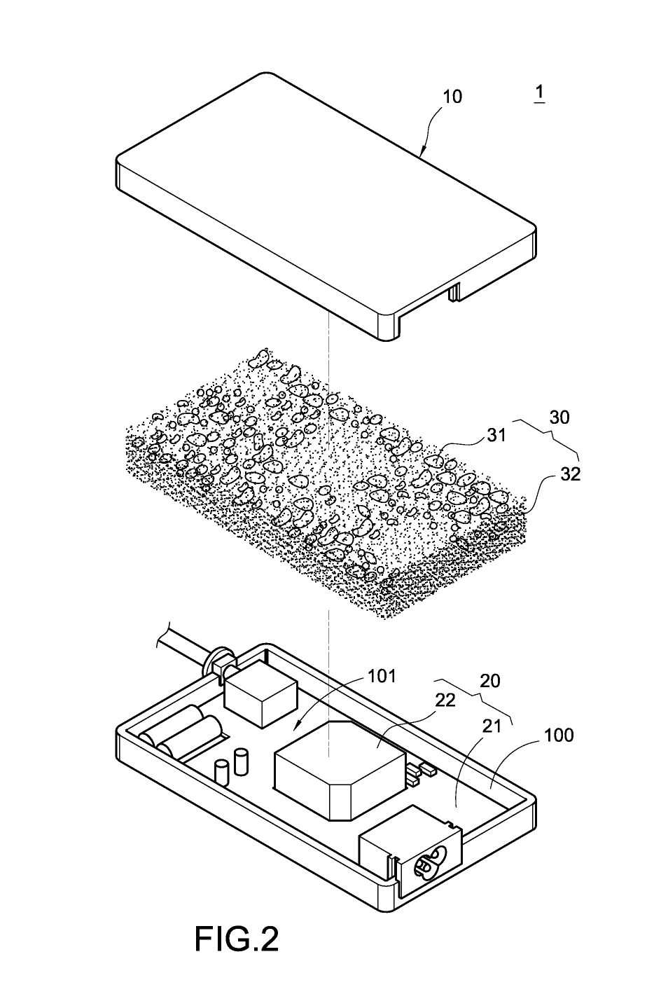

With reference to FIGS. 1 and 2 for a partial perspective cross-sectional view and a perspective exploded view of a power supply with a solid insulating substance in accordance with the present invention respectively, the power supply 1 comprises a casing 10, an electronic module 20 and a filler 30, wherein the power supply 1 can be an AC-AC converter, an AC-DC adapter, a DC-AC inverter or a DC-DC converter.

The casing 10 includes a cavity 100, and the electronic module 20 is installed in the cavity 100. The electronic module 20 includes a circuit board 21 and a plurality of electronic elements 22 electrically coupled to the circuit board 21. After the electronic module 20 is fixed into the cavity 100, a filling space 101 is reserved between the electronic module 20 and an internal wall of the casing 10, and the filler 30 having a solid insulating substance 31 is filled into the filling space 101.

The filler 30 includes the solid insulating substance 31 and an encapsulant 32. After the solid insulating substance 31 and the encapsulant 32 are mixed, the filler is filled into the filling space 101 by a potting method. In this preferred embodiment, the encapsulant 32 is an addition cure 2-part silicone encapsulant, and it is noteworthy to point out that the solid insulating substance 31 is not a solidified encapsulant, and the solid insulating substance 31 is composed for polycarbonate (PC) or nylon, and the solid insulating substance 31 is a material in compliance with the UL 94 standard or any other refractory or fire resistant material. In addition, the solid insulating substance can be made of bakelite, fire resistant (FR) phenol or fire resistant (FR) fiber, and the material can be adjusted or modified slightly according to the actual requirements. The shape of the solid insulating substance 31 includes but not limited to a circular, triangular, square, rectangular, polygonal or irregular shape, or a combination of different shapes. The size of the solid insulating substance 31 is not limited and can be varied with the size of the filling space 101.

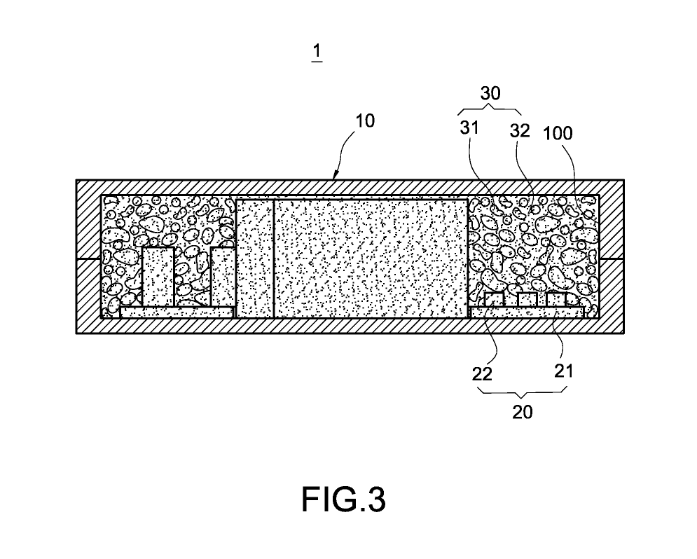

With reference to FIG. 3 for a cross-sectional view of a power supply with a solid insulating substance in accordance with the present invention, the filler 30 is filled between the internal wall of the casing 10 and the electronic module 20. In this preferred embodiment, although the filler 30 is filled up the whole filling space 101, yet it can be filled into the filling space 101 partially according to the requirements of the practical application.

In summation of the description above, the present invention improves over the prior art and complies with the patent application requirements, and thus is duly filed for patent application.

While the invention has been described by means of specific embodiments, numerous modifications and variations could be made thereto by those skilled in the art without departing from the scope and spirit of the invention set forth in the claims.

1. A power supply with a solid insulating substance, comprising:
a casing, having a cavity;
an adapter electronic module, installed in the cavity, and having a filling space reserved from an internal wall of the casing; and
a filler having a solid insulating substance filled into the filling space, and an encapsulant which is an addition cure 2-part silicone, wherein the solid insulating substance is resistant to water, fire, or dust, and the encapsulant is mixed with the solid insulating substance to be hardened in the filling space.

2. The power supply with a solid insulating substance as recited in claim 1, wherein the electronic module includes a circuit board and a plurality of electronic elements electrically coupled to the circuit board.

3. (canceled)

4. (canceled)

5. The power supply with a solid insulating substance as recited in claim 1, wherein the solid insulating substance is composed of polycarbonate (PC).

6. The power supply with a solid insulating substance as recited in claim 1, wherein the solid insulating substance is composed of nylon.

7. The power supply with a solid insulating substance as recited in claim 1, wherein the solid insulating substance is a material in compliance with the UL 94 standard.

8. The power supply with a solid insulating substance as recited in claim 1, wherein the solid insulating substance is composed of a fire resistant material.

9. The power supply with a solid insulating substance as recited in claim 1, wherein the solid insulating substance is one selected from the collection of bakelite, fire resistant (FR) phenol and fire resistant (FR) fiber.

10. The power supply with a solid insulating substance as recited in claim 1, wherein the solid insulating substance is not a solidified encapsulant.

11. The power supply with a solid insulating substance as recited in claim 1, wherein the solid insulating substance is in a circular, triangular, square, rectangular, polygonal or irregular shape.

12. The power supply with a solid insulating substance as recited in claim 1, wherein the solid insulating substance has a size varied with the size of the filling space.

13. The power supply with a solid insulating substance as recited in claim 1, wherein the power supply is an AC-AC converter, an AC-DC adapter, a DC-AC inverter or a DC-DC converter.
